(19) United States
(12) Patent Application Publication
(10) Pub. No.: US 2026/0047352 A1
(43) Pub. Date: Feb. 12, 2026

(54) RESISTIVE RANDOM ACCESS MEMORY AND METHOD OF FORMING THE SAME

(71) Applicant: United Microelectronics Corp., Hsinchu (TW)

(72) Inventors: Shih-Ming Lin, Kaohsiung City (TW); Yang-Ju Lu, Changhua County (TW); Yu-Lung Shih, Tainan City (TW)

(73) Assignee: United Microelectronics Corp., Hsinchu (TW)

(21) Appl. No.: 18/822,482

(22) Filed: Sep. 3, 2024

(30) Foreign Application Priority Data
Aug. 12, 2024 (TW) 113130090

(51) Int. Cl. H10N 70/00; H10B 63/00; H10N 70/20

(52) U.S. Cl. CPC H10N 70/828; H10B 63/00; H10N 70/046; H10N 70/24

(57) ABSTRACT

A resistive random access memory and a method of forming the same are provided. The resistive random access memory includes a first electrode, a resistance switch layer located on the first electrode, a second electrode located on the resistance switch layer, and a plurality of nanoparticles located between the resistance switch layer and the second electrode.

### CROSS-REFERENCE TO RELATED APPLICATION

This application claims the priority benefit of Taiwan application serial no. 113130090, filed on Aug. 12, 2024. The entirety of the above-mentioned patent application is hereby incorporated by reference herein and made a part of this specification.

### BACKGROUND

### Technical Field

The disclosure relates to a memory device, and in particular, relates to a resistive random access memory (ReRAM) and a method of forming the same.

### Description of Related Art

The main structure of a resistive random access memory includes two layers of electrodes, the upper and lower electrodes, and a resistance switch layer in between. In the resistive random access memory, data is written or erased by controlling the write voltage to change the resistance value of the data storage.

At present, the mainstream explanation of the switching mechanism of the resistive random access memory is based on the Filament Theory summarized as follows. After a resistive random access memory is manufactured, a large bias voltage is applied to it, causing the oxygen vacancies inside the resistance switch layer to form multiple conductive paths similar to filaments, and the current is conducted through these filaments. Since the current can flow in the resistive random access memory at this time, the resistive random access memory is in a low resistance state (LRS). This step is called the filament forming step. Next, a bias voltage is applied to control the recombination of oxygen ions and oxygen vacancies, thus disconnecting the conductive paths and allowing the resistive random access memory to return from the low resistance state (LRS) to a high resistance state (HRS). This process is called a reset step. If a voltage lower than that required in the forming step is applied again, the disconnected conductive paths may be reconnected, so that the resistive random access memory returns from the high resistance state (HRS) to the low resistance state (LRS). This process is called a set step. If the above set and reset steps are repeated, the writing and erasing of the resistive random access memory may be achieved.

However, the filaments of the resistive random access memory are randomly distributed in the resistance switch layer, resulting in unstable set and reset operations of the device.

### SUMMARY

Based on the above problem, the disclosure provides a resistive random access memory and a method of forming the same to solve the problem that the filaments of the resistive random access memory are randomly distributed in a resistance switch layer, resulting in unstable set and reset operations.

An embodiment of the disclosure provides a resistive random access memory including a first electrode, a resistance switch layer located on the first electrode, a second electrode located on the resistance switch layer, and a plurality of nanoparticles located between the resistance switch layer and the second electrode.

In some embodiments, the plurality of nanoparticles provide oxygen vacancies and a starting point of conductive paths (filaments).

In some embodiments, a size of each of the plurality of nanoparticles is 1 nanometer to 10 nanometers.

In some embodiments, the plurality of nanoparticles include a plurality of nanocrystals.

In some embodiments, each of the plurality of nanoparticles includes an inner portion and an outer portion, and an oxygen content of the outer portion is higher than an oxygen content of the inner portion.

In some embodiments, the plurality of nanoparticles include a metal.

In some embodiments, the plurality of nanoparticles include a transition metal.

An embodiment of the disclosure provides a method of forming a resistive random access memory, and the method includes the following steps. A first electrode is formed. A resistance switch layer is formed on the first electrode. A metal film and an oxide sacrificial layer are sequentially formed on the resistance switch layer. A heat treatment is performed to form the oxide sacrificial layer into an oxide layer, and the metal film is formed into a plurality of nanoparticles at an interface between the resistance switch layer and the oxide layer. The oxide layer is removed. A second electrode is formed on the resistance switch layer and the plurality of nanoparticles.

In some embodiments, the plurality of nanoparticles provide oxygen vacancies and a starting point of conductive paths (filaments) located on the resistance switch layer.

In some embodiments, a size of each of the plurality of nanoparticles is 1 nanometer to 10 nanometers.

In some embodiments, the plurality of nanoparticles include a plurality of nanocrystals.

In some embodiments, each of the plurality of nanoparticles includes an inner portion and an outer portion, and an oxygen content of the outer portion is higher than an oxygen content of the inner portion.

In some embodiments, the plurality of nanoparticles include a metal.

In some embodiments, the plurality of nanoparticles include a transition metal.

In some embodiments, the resistance switch layer includes a U-shaped structure. A thickness of the metal film is 1 nanometer to 10 nanometers.

In some embodiments, the metal film includes Ta, Ni, Ti, Hf, Zr, Zn, W, Co, Nb, Fe, Cu, Cr, Sr, or a combination thereof.

In some embodiments, a thickness of the oxide sacrificial layer is 10 nanometers to 100 nanometers.

In some embodiments, the oxide sacrificial layer includes silicon oxide, silicon nitride, or silicon oxynitride.

In some embodiments, a temperature of the heat treatment is 200 degrees to 800 degrees.

In some embodiments, after the oxide layer is removed, the plurality of nanoparticles are exposed from a top surface of the resistance switch layer.

To sum up, in the resistive random access memory provided by the disclosure, nanoparticles are formed on the surface of the resistance switch layer, so that the filaments of the resistive random access memory form a more certain path, and the stability of the operation of the resistive random access memory is thereby improved.

In addition, in the method of forming the resistive random access memory provided by the disclosure, nanoparticles can be formed on the surface of the resistance switch layer by sequentially coating the metal film and the oxide sacrificial layer on the surface of the resistance switch layer and then performing the heat treatment. It is thus a more favorably way to effectively improve the performance of the resistive random access memory by a method that can be easily achieved in the semiconductor manufacturing process.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 to FIG. 4 are cross-sectional schematic views of a method of forming a resistive random access memory according to an embodiment of the disclosure.

### DESCRIPTION OF THE EMBODIMENTS

The disclosure is more comprehensively described with reference to the figures of the present embodiments. However, the disclosure can also be implemented in various different forms, and is not limited to the embodiments in the present specification. The sizes and distances of the polygons in the drawings are drawn for visual clarity and are not their original sizes and distances. The same or similar reference numerals represent the same or similar elements and will not be described in detail in the following paragraphs.

As used herein, “connected” may refer to physical and/or electrical connections, and “electrical connection” or “coupling” may include the presence of other elements between two elements.

As used herein, “about”, “approximately”, or “substantially” includes the stated value and the mean within an acceptable deviation range of the particular value that a person having ordinary skill in the art can determine, taking into account the measurement in question and the particular amount of error associated with that measurement (i.e., a limitation of a measurement system). For example, “about” may mean within one or more standard deviations, or within, for example, ±30%, ±20%, ±15%, ±10%, and ±5% of the stated value. Moreover, a relatively acceptable range of deviation or standard deviation may be chosen for the term “about”, “approximately”, or “substantially” as used herein based on optical properties, etching properties or other properties, instead of applying one standard deviation across all the properties.

The terminology used herein is for the purpose of describing exemplary embodiments only and is not intended to be limiting of the disclosure. In this case, the singular form includes the plural form unless otherwise explained in the context.

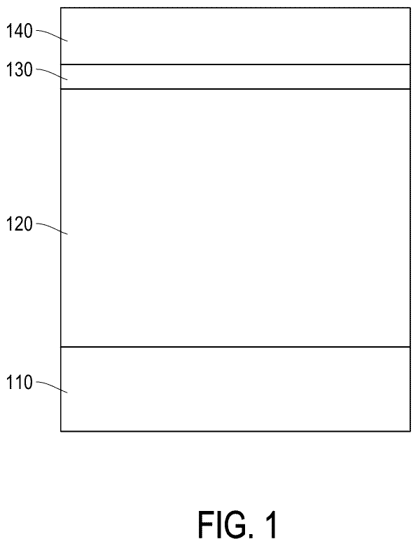

FIG. 1 to FIG. 4 are cross-sectional schematic views of a method of forming a resistive random access memory 10 according to an embodiment of the disclosure.

As shown in FIG. 1, a first electrode 110 is formed.

In some embodiments, the first electrode 110 may include various conductive materials, such as gold (Au), platinum (Pt), ruthenium (Ru), iridium (Ir), titanium (Ti), aluminum (Al), copper (Cu), tantalum (Ta), tungsten (W), or an alloy of the foregoing, but the disclosure is not limited thereto.

In some embodiments, the first electrode 110 may be formed by a process such as chemical vapor deposition (CVD) or physical vapor deposition (PVD), but the disclosure is not limited thereto.

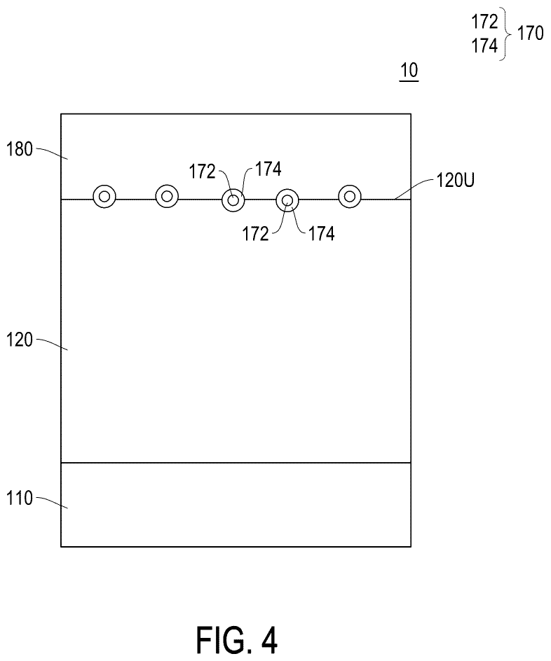

The first electrode 110 may be used as a bottom electrode of the resistive random access memory 10 as shown in FIG. 4.

Next, as shown in FIG. 1, a resistance switch layer 120 is formed on the first electrode 110.

The resistance switch layer 120 may be formed on the first electrode 110 in various shapes as needed, for example, in a U-shaped structure or an inverted U-shaped structure. Alternatively, as shown in FIG. 1, the resistance switch layer 120 is formed on the first electrode 110 in a block structure. The disclosure may be applied to various shapes of resistance switch layers 120 and is not limited to the abovementioned structure.

Herein, the resistance switch layer 120 has a resistance switch characteristic, that is, its resistance changes according to the applied voltage.

In some embodiments, the resistance switch layer 120 may include a dielectric layer and become a conductor or an insulator depending on the applied voltage.

In some embodiments, the resistance switch layer 120 may include a transition metal oxide, such as Ta₂O₅, NiO, TiO₂, HfO, ZrO, ZnO, WO₃, CoO, Nb₂O₅, Fe₂O₃, CuO, CrO₂, SrZrO₃, and/or other resistance switch materials to be developed in the future.

In some embodiments, the resistance switch layer 120 may be formed by processes such as chemical vapor deposition (CVD), physical vapor deposition (PVD), and atomic layer deposition (ALD), but the disclosure is not limited thereto.

Next, as shown in FIG. 1, a metal film 130 and an oxide sacrificial layer 140 are sequentially formed on the resistance switch layer 120.

In some embodiments, an excessively thin metal film 130 may be deposited on the resistance switch layer 120 in various ways, and a thickness of the metal film 130 is approximately 1 nanometer to 10 nanometers, and more preferably, approximately several nanometers, such as less than 5 nanometers.

In some embodiments, the metal film 130 may include various metals. In some embodiments, the metal film 130 may include a transition metal, such as Ta, Ni, Ti, Hf, Zr, Zn, W, Co, Nb, Fe, Cu, Cr, or Sr, or a combination thereof.

In some embodiments, the metal film 130 may be formed by processes such as chemical vapor deposition (CVD), physical vapor deposition (PVD), and atomic layer deposition (ALD), but the disclosure is not limited thereto.

In some embodiments, a thickness of the oxide sacrificial layer 140 is 10 nanometers to 100 nanometers.

In some embodiments, the oxide sacrificial layer 140 includes silicon oxide, silicon nitride, or silicon oxynitride.

In some embodiments, the oxide sacrificial layer 140 may be formed by processes such as chemical vapor deposition (CVD), physical vapor deposition (PVD), and atomic layer deposition (ALD), but the disclosure is not limited thereto.

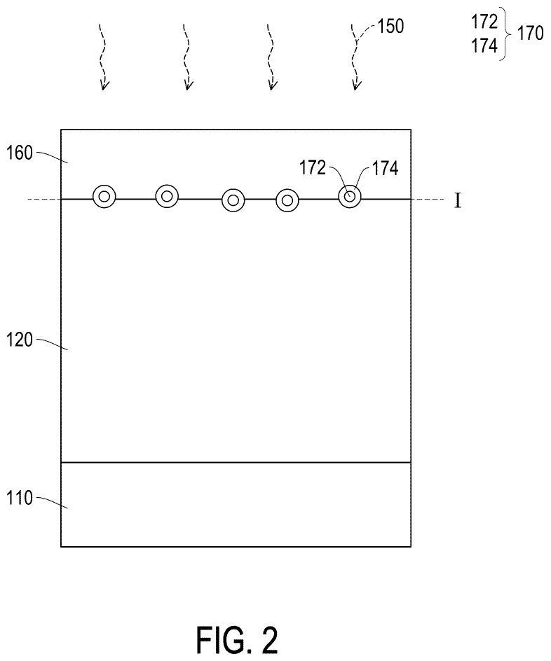

Next, as shown in FIG. 2, by performing a heat treatment 150 on the structure shown in FIG. 1, the oxide sacrificial layer 140 is formed into an oxide layer 160, and the metal film 130 is formed into a plurality of nanoparticles 170 at an interface I between the resistance switch layer 120 and the oxide layer 160.

Herein, the heat treatment 150 is used to control the formation of the plurality of nanoparticles 170. That is, by the heat treatment 150, the metal film 130 is reduced to a spherical metal at the interface I between the resistance switch layer 120 and the oxide layer 160 due to cohesive force and is combined with oxygen in the surrounding resistance switch layer 120 and oxide layer 160 at its periphery to form the nanoparticles 170 with an oxide film surrounding the metal or a structure in which an oxygen content of an inner portion 172 of each nanoparticle 170 is lower than an oxygen content of an outer portion 174 of each nanoparticle 170. Further, since the formation of the plurality of nanoparticles 170 is due to the spherical metal formed by the cohesive force of the metal film 130 and the oxygen of the surrounding resistance switch layer 120 and the oxide layer 160, the formation of the plurality of nanoparticles 170 also provides oxygen vacancies.

Herein, a temperature of the heat treatment 150 is determined by factors such as the oxygen-snatching ability and free energy of the metal film 130 used. Further, the temperature of the heat treatment 150 may be used to control a size of each of the plurality of nanoparticles 170.

In some embodiments, the heat treatment 150 may be a process such as an annealing process, but the disclosure is not limited thereto.

In some embodiments, the temperature of the heat treatment 150 is approximately 100 degrees to 1,000 degrees, and more preferably, approximately 200 degrees to 800 degrees.

In some embodiments, the size of each of the plurality of nanoparticles 170 is approximately 1 nanometer to 10 nanometers, more preferably, approximately several nanometers, such as a particle size less than 5 nanometers.

In some embodiments, the plurality of nanoparticles 170 include a plurality of nanocrystals.

In addition, under a transmission electron microscope (TEM), it can be seen that each of the plurality of nanoparticles 170 includes the inner portion 172 and the outer portion 174. This is a structure in which the oxygen content of the outer portion 174 of each nanoparticle 170 is higher than the oxygen content of the inner portion 172 of each nanoparticle 170. For instance, the inner portion 172 of each nanoparticle 170 is metal, and the outer portion 174 of each nanoparticle 170 is an oxide layer, forming a plurality of nanoparticles 170 similar to a core-shell structure.

As described above, since the plurality of nanoparticles 170 are formed by the cohesive force of the metal film 130 after the heat treatment 150, the plurality of nanoparticles 170, like the metal film 130, may include various metals and transition metals, such as Ta, Ni, Ti, Hf, Zr, Zn, W, Co, Nb, Fe, Cu, Cr, Sr, or a combination thereof.

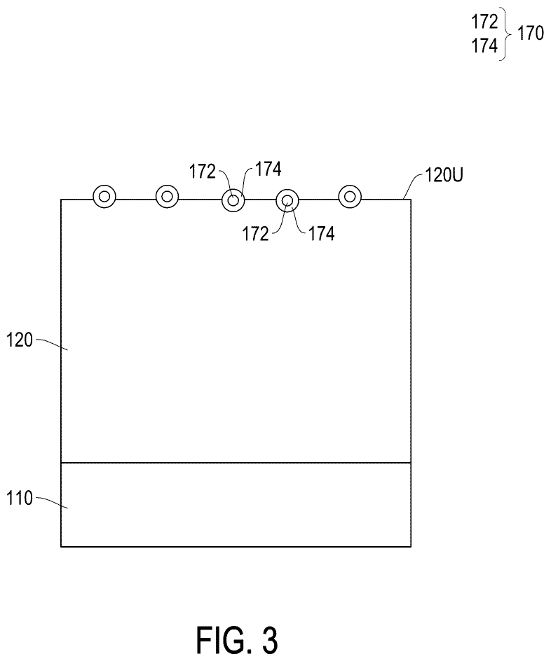

Next, as shown in FIG. 3, the oxide layer 160 is removed by a high selectivity removal method, and the plurality of nanoparticles 170 including, for example, a metal and the resistance switch layer 120 including, for example, a transition metal oxide are retained. In this way, after the oxide layer 160 is removed, the plurality of nanoparticles 170 are exposed from a top surface 120U of the resistance switch layer 120.

Herein, as shown in FIG. 3, the step of removing the oxide layer 160 may be performed using various etching removal methods, including wet etching, dry etching, chemical mechanical planarization (CMP), etc., and all of which may be applied in the disclosure. Further, the removal step is not limited to the abovementioned step. Any etching removal method that can leave the plurality of nanoparticles 170 on the top surface 120U of the resistance switch layer 120 can be used. Moreover, the etching removal method and the number of times selected depend on the selected material.

For instance, in some embodiments, two wet etching steps may be used. The oxide layer 160 is first removed, and then another wet etching step is applied to remove the excess metal film 130, stopping at the top surface 120U of the resistance switch layer 120 including a transition metal oxide, and the plurality of nanoparticles 170 are kept. Alternatively, in some embodiments, the abovementioned effect may be achieved by performing wet etching, alternately performing dry-wet etching, or by performing multiple dry etching steps. Further, in some embodiments, the oxide layer 160 on the top surface 120U of the resistance switch layer 120 may be removed by highly selective chemical mechanical planarization. For instance, a highly selective polishing slurry that removes oxide and stops at the metal is used, so that the plurality of nanoparticles 170 are exposed on the top surface 120U of the planarized resistance switch layer 120. That is, the plurality of nanoparticles 170 are exposed from the top surface 120U of the resistance switch layer 120 in a pointed shape.

After the step of removing the oxide layer 160, the plurality of nanoparticles 170 with the pointed shape may provide a higher electric field on the top surface 120U of the resistance switch layer 120 and create oxygen vacancies caused by the formation of the plurality of nanoparticles 170 as described above. These factors make the plurality of nanoparticles 170 a starting point for the generation of filaments, so that the filaments of the resistive random access memory 10 form a more certain path, and the stability of the operation of the resistive random access memory 10 is thereby improved.

Next, as shown in FIG. 4, a second electrode 180 is formed on the resistance switch layer 120 and the plurality of nanoparticles 170.

Herein, the second electrode 180 may be used as a top electrode of the resistive random access memory 10.

In some embodiments, the second electrode 180, like the first electrode 110, may include various conductive materials, such as gold (Au), platinum (Pt), ruthenium (Ru), iridium (Ir), titanium (Ti), aluminum (Al), copper (Cu), tantalum (Ta), tungsten (W), or an alloy of the foregoing.

In an embodiment, the second electrode 180 may be made of a material different from that of the first electrode 110, such as the first electrode 110 is tungsten (W) and the second electrode 180 is copper (Cu). In another embodiment, the second electrode 180 may be made of the same material as the first electrode 110.

In some embodiments, the second electrode 180 may be formed on the top surface 120U of the resistance switch layer 120 and the plurality of nanoparticles 170 by using processes such as chemical vapor deposition (CVD) or physical vapor deposition (PVD).

Herein, the plurality of nanoparticles 170 provide oxygen vacancies and the starting point for the formation of filaments in the resistance switch layer 120 to provide the resistive random access memory 10 as shown in FIG. 4, so that the filaments in the resistance switch layer 120 form a more certain path. In this way, in the resistive random access memory 10, the problem of unstable set and reset operations of the device due to the random distribution of filaments in the resistance switch layer 120 is solved, and the stability of the operation of the resistive random access memory 10 is improved.

For instance, after the heat treatment 150 such as annealing, the resistance switch layer 120 formed of Ta₂O₅ and the metal film 130 formed of Ta form dot-shaped Ta and the plurality of nanoparticles 170 formed of tantalum oxide (TaOₓ) on the top surface 120U of the resistance switch layer 120, promoting the formation of oxygen barrier vacancies and the starting point of the formation of filaments in the resistance switch layer 120. In this way, the filaments are formed in a relatively fixed arrangement direction, so that the operation stability of the resistive random access memory 10 is improved.

In addition, the first electrode 110 and the second electrode 180 may be connected to various internal connection structures (not shown) to operate or read the resistive random access memory 10 and enable it to send or receive signals with other circuits and/or active components.

Therefore, in the resistive random access memory provided by the disclosure, nanoparticles are formed on the surface of the resistance switch layer, so that the filaments of the resistive random access memory form a more certain path, and the stability of the operation of the resistive random access memory is thereby improved.

Further, in the method of forming the resistive random access memory provided by the disclosure, nanoparticles can be formed on the surface of the resistance switch layer by sequentially coating the metal film and the oxide sacrificial layer on the surface of the resistance switch layer and then performing the heat treatment. It is thus a more favorably way to effectively improve the performance of the resistive random access memory by a method that can be easily achieved in the semiconductor manufacturing process.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A resistive random access memory, comprising:
a first electrode;
a resistance switch layer located on the first electrode;
a second electrode located on the resistance switch layer; and
a plurality of nanoparticles located between the resistance switch layer and the second electrode.

2. The resistive random access memory according to claim 1, wherein the plurality of nanoparticles provide oxygen vacancies and a starting point of conductive paths (filaments).

3. The resistive random access memory according to claim 1, wherein a size of each of the plurality of nanoparticles is 1 nanometer to 10 nanometers.

4. The resistive random access memory according to claim 1, wherein the plurality of nanoparticles comprise a plurality of nanocrystals.

5. The resistive random access memory according to claim 1, wherein each of the plurality of nanoparticles comprises an inner portion and an outer portion, wherein an oxygen content of the outer portion is higher than an oxygen content of the inner portion.

6. The resistive random access memory according to claim 1, wherein the plurality of nanoparticles comprise a metal.

7. The resistive random access memory according to claim 1, wherein the plurality of nanoparticles comprise a transition metal.

8. A method of forming a resistive random access memory, comprising:
forming a first electrode;
forming a resistance switch layer on the first electrode;
sequentially forming a metal film and an oxide sacrificial layer on the resistance switch layer;
performing a heat treatment to form the oxide sacrificial layer into an oxide layer and forming the metal film into a plurality of nanoparticles at an interface between the resistance switch layer and the oxide layer;
removing the oxide layer; and
forming a second electrode on the resistance switch layer and the plurality of nanoparticles.

9. The method of forming the resistive random access memory according to claim 8, wherein the plurality of nanoparticles provide oxygen vacancies and a starting point of conductive paths (filaments) located on the resistance switch layer.

10. The method of forming the resistive random access memory according to claim 8, wherein a size of each of the plurality of nanoparticles is 1 nanometer to 10 nanometers.

11. The method of forming the resistive random access memory according to claim 8, wherein the plurality of nanoparticles comprise a plurality of nanocrystals.

12. The method of forming the resistive random access memory according to claim 8, wherein each of the plurality of nanoparticles comprises an inner portion and an outer portion, wherein an oxygen content of the outer portion is higher than an oxygen content of the inner portion.

13. The method of forming the resistive random access memory according to claim 8, wherein the plurality of nanoparticles comprise a metal.

14. The method of forming the resistive random access memory according to claim 8, wherein the plurality of nanoparticles comprise a transition metal.

15. The method of forming the resistive random access memory according to claim 8, wherein a thickness of the metal film is 1 nanometer to 10 nanometers.

16. The method of forming the resistive random access memory according to claim 8, wherein the metal film comprises Ta, Ni, Ti, Hf, Zr, Zn, W, Co, Nb, Fe, Cu, Cr, Sr, or a combination thereof.

17. The method of forming the resistive random access memory according to claim 8, wherein a thickness of the oxide sacrificial layer is 10 nanometers to 100 nanometers.

18. The method of forming the resistive random access memory according to claim 8, wherein the oxide sacrificial layer comprises silicon oxide, silicon nitride, or silicon oxynitride.

19. The method of forming the resistive random access memory according to claim 8, wherein a temperature of the heat treatment is 200 degrees to 800 degrees.

20. The method of forming the resistive random access memory according to claim 8, wherein after the oxide layer is removed, the plurality of nanoparticles are exposed from a top surface of the resistance switch layer.
